(19) United States
(12) Patent Application Publication
(10) Pub. No.: US 2025/0230550 A1
(43) Pub. Date: Jul. 17, 2025

(54) METALLIZED RESIN FILM, PRINTED WIRING BOARD, CURRENT COLLECTOR FILM FOR LITHIUM ION BATTERIES, AND METHOD FOR MANUFACTURING METALLIZED RESIN FILM

(71) Applicant: KANEKA CORPORATION, Osaka (JP)

(72) Inventor: Takashi Itoh, Otsu-shi (JP)

(73) Assignee: KANEKA CORPORATION, Osaka (JP)

(21) Appl. No.: 19/098,549

(22) Filed: Apr. 2, 2025

Related U.S. Application Data
(63) Continuation of application No. PCT/JP2023/034921, filed on Sep. 26, 2023.

(30) Foreign Application Priority Data
Oct. 17, 2022 (JP) 2022-166493

(51) Int. Cl. C23C 18/16; C23C 18/20; C23C 18/22; C23C 18/40; H01M 4/66; H05K 1/03; H05K 3/18

(52) U.S. Cl. CPC C23C 18/1641; C23C 18/2086; C23C 18/22; C23C 18/40; H01M 4/661; H01M 4/666; H01M 4/667; H05K 1/0373; H05K 3/181; H05K 2201/0154; H05K 2201/0209

(57) ABSTRACT

A metallized resin film includes a resin composition layer, an electroless copper plating layer, and an adhesion layer including ionic copper interposed between the resin composition layer and the electroless copper plating layer. The resin composition layer includes a metal oxide particle and a polyimide-based resin having a storage modulus of 0.02 GPa or more at a temperature of 300° C. The adhesion layer has a light reflectance of 30% or less.

### TECHNICAL FIELD

One or more embodiments of the present invention relate to a metallized resin film, a printed wiring board, a current collector film for lithium ion batteries, and a method for manufacturing a metallized resin film.

### BACKGROUND

Printed wiring boards including a circuit including a metal conductor on an insulating circuit board are widely used as a circuit board for mounting of various electronic components. As electronic devices are highly functionalized, improved in performance, and downsized, printed wiring boards are required to have a further narrow circuit wiring pitch. Specifically, there is a demand for a printed wiring board in which a circuit having a narrow pitch is formed in a flexible film portion, such as a flexible printed wiring board, a rigid flex circuit board, a multilayer flexible circuit board, or a chip on film (COF), which can be compactly folded and housed inside an electronic device.

Patent Document 1 discloses a method in which a thin film copper foil with a carrier is bonded to a polyimide sheet, as a method coping with formation of a circuit having a narrow pitch. Patent Document 2 discloses a method in which a metal layer is formed on a polyimide film with a vacuum vapor deposition method, a sputtering method, an ion plating method, or the like.

Formation of a circuit having a narrow pitch needs improvement in adhesion between an insulating substrate and a copper foil. In the method described in Patent Document 1, unevenness is intentionally formed on the copper foil surface in order to ensure adhesion between an insulating substrate and the copper foil. However, in the method described in Patent Document 1, the surface of the insulating substrate is roughened by the unevenness on the copper foil surface, and therefore the pitch is difficult to narrow, and the transmission characteristics tend to deteriorate.

In the method described in Patent Document 2, a metal layer containing nickel, chromium, vanadium, titanium, molybdenum, or the like is formed as a ground metal layer of a copper layer on the substrate surface. However, in the method described in Patent Document 2, complete removal of the ground metal layer is not achieved by only etching with an etching solution for copper at the time of circuit formation, and needs use of another etching solution for the ground metal layer.

Patent Document 3 discloses an example in which copper plating is directly performed by electroless plating on a material layer containing a polyimide having a silicone structure and fumed silica.

### PATENT DOCUMENTS

Patent Document 1: JP 2005-76091 A
Patent Document 2: JP 6706013 B1
Patent Document 3: JP 5037168 B2

In the method described in Patent Document 3, an electroless copper plating layer can be directly formed on a resin film surface having low roughness. However, the technique described in Patent Document 3 still has room for improvement in enhancing the solder heat resistance after moisture absorption treatment (hereinafter, simply described to as “solder heat resistance”).

### SUMMARY

One or more embodiments of the present invention have been made in view of the above. In one aspect, embodiments disclosed herein relate to a metallized resin film excellent in solder heat resistance and capable of coping with formation of a circuit having a narrow pitch, and a method for manufacturing the metallized resin film. In another aspect, embodiments disclosed herein relate to a printed wiring board and a current collector film for lithium ion batteries manufactured using the metallized resin film.

One or more embodiments of the present invention are as follows.

[1] A metallized resin film including:
a resin composition layer;
an electroless copper plating layer; and
an adhesion layer interposed between the resin composition layer and the electroless copper plating layer,
the resin composition layer containing a polyimide-based resin having a storage modulus of 0.02 GPa or more at a temperature of 300° C., the resin composition layer containing a metal oxide particle, the adhesion layer containing ionic copper and having a light reflectance of 30% or less.

[2] The metallized resin film according to [1], in which the metal oxide particle is a silica particle.

[3] The metallized resin film according to [2], in which the silica particle is a fumed silica particle.

[4] The metallized resin film according to any one of [1] to [3], in which the polyimide-based resin has a linear expansion coefficient of 30 ppm/K or more and 100 ppm/K or less.

[5] The metallized resin film according to any one of [1] to [4], in which the polyimide-based resin has one or more diamine residues selected from the group consisting of a 2,2′-bis(trifluoromethyl)benzidine residue, a 4,4′-oxydianiline residue, a 1,3-bis(4-aminophenoxy)benzene residue, a 2,2-bis[4-(4-aminophenoxy)phenyl]propane residue, a 2,2′-dimethylbenzidine residue, and a p-phenylenediamine residue, and one or more tetracarboxylic dianhydride residues selected from the group consisting of a 4,4′-oxydiphthalic anhydride residue, a 3,3′,4,4′-biphenyltetracarboxylic dianhydride residue, and a pyromellitic dianhydride residue.

[6] The metallized resin film according to any one of [1] to [5], in which the resin composition layer has a main surface on a side of the adhesion layer, the main surface having an arithmetic average roughness Ra of 220 nm or less.

[7] A printed wiring board including the metallized resin film according to any one of [1] to [6].

[8] A current collector film for lithium ion batteries, including the metallized resin film according to any one of [1] to [6].

[9] A method for manufacturing a metallized resin film, the method including forming an electroless copper plating layer on a resin composition layer that is desmeared, the resin composition layer containing a polyimide-based resin having a storage modulus of 0.02 GPa or more at a temperature of 300° C., and the resin composition layer containing a metal oxide particle.

According to one or more embodiments of the present invention, a metallized resin film can be provided that is excellent in solder heat resistance and capable of coping with formation of a circuit having a narrow pitch, and a method for manufacturing the metallized resin film can be provided. Furthermore, according to one or more embodiments of the present invention, it is also possible to provide a printed wiring board and a current collector film for lithium ion batteries manufactured using the metallized resin film.

### BRIEF DESCRIPTION OF THE DRAWINGS

FIG. 1 is a sectional view showing an example of a metallized resin film according to one or more embodiments of the present invention.

FIG. 2 is a sectional view showing another example of a metallized resin film according to one or more embodiments of the present invention.

FIG. 3 is a sectional view showing another example of a metallized resin film according to one or more embodiments of the present invention.

FIG. 4 shows an example of spectrum data obtained by analyzing a metallized resin film by X-ray photoelectron spectroscopy.

FIG. 5 is a graph obtained by normalizing the spectral intensity in FIG. 4.

### DETAILED DESCRIPTION

One or more embodiments of the present invention will be described in detail below, but the present invention is not limited to these embodiments. The academic documents and the patent documents mentioned in the present description are incorporated in the present description by reference in their entirety.

First, terms used in the present description will be described. The term “metal” also means silicon (Si), which is generally classified as a metalloid. The term “structural unit” refers to a repeating unit included in a polymer. The term “polyimide” refers to a polymer including a structural unit represented by the following general formula (1) (hereinafter, sometimes described as “structural unit (1)”).

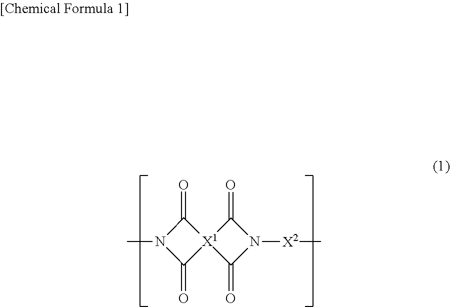

In the general formula (1), X¹ represents a tetracarboxylic dianhydride residue (tetravalent organic group derived from tetracarboxylic dianhydride), and X² represents a diamine residue (divalent organic group derived from a diamine).

The content rate of the structural unit (1) with respect to all of the structural units included in the polyimide may be, for example, 50 mol % or more and 100 mol % or less, 60 mol % or more and 100 mol % or less, 70 mol % or more and 100 mol % or less, 80 mol % or more and 100 mol % or less, 90 mol % or more and 100 mol % or less, or 100 mol %.

The term “polyamic acid” refers to a polymer including a structural unit represented by the following general formula (2) (hereinafter, sometimes described as “structural unit (2)”).

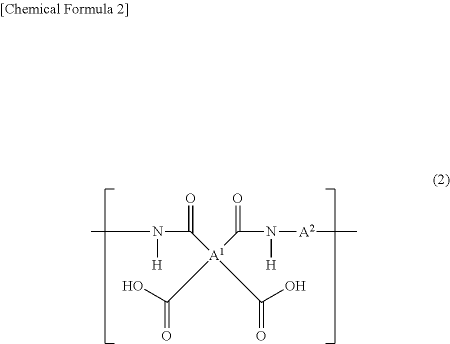

In the general formula (2), A¹ represents a tetracarboxylic dianhydride residue (tetravalent organic group derived from tetracarboxylic dianhydride), and A² represents a diamine residue (divalent organic group derived from a diamine).

The content rate of the structural unit (2) with respect to all of the structural units included in the polyamic acid may be, for example, 50 mol % or more and 100 mol % or less, 60 mol % or more and 100 mol % or less, 70 mol % or more and 100 mol % or less, 80 mol % or more and 100 mol % or less, 90 mol % or more and 100 mol % or less, or 100 mol %.

A polyimide is an imidized product of a polyamic acid. Therefore, in a case where the content rate of the structural unit (2) with respect to all of the structural units forming the polyamic acid is 100 mol %, a polyimide that is an imidized product of the polyamic acid has a residue represented by A¹ in the general formula (2) as X¹ in the general formula (1), and a residue represented by A² in the general formula (2) as X² in the general formula (1).

The term “fumed metal oxide particle” refers to a dry metal oxide particle obtained by a flame hydrolysis method, an arc method, a plasma method, or the like.

The term “copper having ionicity (ionic copper)” means copper having a site having a charge (ionic site). The “reflectance of light (light reflectance)” is an average reflectance of light having a wavelength of 300 nm to 800 nm, unless otherwise specified. The method of measuring the light reflectance is the same as or similar to the method in Examples described below. The “linear expansion coefficient” is a coefficient of linear expansion during temperature rise from 100° C. to 200° C., unless otherwise specified. The method of measuring the linear expansion coefficient is the same as or similar to the method in Examples described below.

The “main surface” of a layered material (more specifically, resin composition layer, electroless copper plating layer, adhesion layer, electrolytic copper plating layer, non-thermoplastic polyimide layer, metallized resin film, copper-clad laminate, or the like) refers to a surface orthogonal to the thickness direction of the layered material. The value of the “thickness (film thickness)” of the layered material is the arithmetic average of 10 measured values obtained by observing a section of the layered material cut in the thickness direction with an electron microscope, selecting 10 measurement points at random from the sectional image, and measuring the thicknesses at the 10 selected measurement points, unless otherwise specified.

The term “non-thermoplastic polyimide” refers to a polyimide that retains a film shape (flat film shape) when fixed in a film state to a metallic fixation frame and heated at a heating temperature of 380° C. for 1 minute.

Hereinafter, the name of a compound may be followed by the term “-based” to collectively refer to the compound and its derivatives. The term “-based” following the name of a compound to express the name of a polymer means that repeating units of the polymer are derived from the compound or its derivative, unless otherwise specified. The tetracarboxylic dianhydride may be described as “acid dianhydride.”

The components, the functional groups, and the like shown in the present description may be used alone or in combination of two or more kinds thereof, unless otherwise specified.

In the drawings that are referred to in the following description, the constituent elements are schematically shown for easy understanding, and the size, the number, the shape, and the like of each illustrated constituent element may be different from the actual counterparts for convenience of preparing the drawings. For convenience of description, in the drawings described below, the same constituent part as in a previously described drawing will be given the same reference sign as in the previously described drawing, and the description of the constituent part may be omitted.

### FIRST EMBODIMENT: METALLIZED RESIN FILM

### Summary of First Embodiment

A metallized resin film according to First Embodiment of the present invention (hereinafter, sometimes described as “specified metallized resin film”) includes a resin composition layer, an electroless copper plating layer, and an adhesion layer interposed between the resin composition layer and the electroless copper plating layer. The resin composition layer contains a polyimide-based resin having a storage modulus of 0.02 GPa or more at a temperature of 300° C., and contains a metal oxide particle. The adhesion layer contains ionic copper and has a light reflectance of 30% or less.

Hereinafter, the resin composition layer may be described as “layer A”. The electroless copper plating layer may be described as “layer B”. The adhesion layer may be described as “layer C”.

Hereinafter, the term “storage modulus” means the storage modulus at a temperature of 300° C., unless otherwise specified. The method of measuring the storage modulus of the polyimide-based resin is the same as or similar to the method in Examples described below. The storage modulus of the polyimide-based resin can be adjusted by the kind of a monomer used in synthesis of the polyimide-based resin. For an increase in the storage modulus of the polyimide-based resin, it is effective to use a monomer having a rigid chemical structure and increase the composition ratio of the monomer.

The specified metallized resin film is excellent in solder heat resistance and can cope with formation of a circuit having a narrow pitch. The reason for this is presumed as follows.

The layer A of the specified metallized resin film contains the polyimide-based resin having a storage modulus of 0.02 GPa or more at a temperature of 300° C. Therefore, the polyimide-based resin has a certain elastic modulus or more even in the vicinity of the melting point of solder. Thus, the specified metallized resin film is excellent in solder heat resistance.

Furthermore, as a result of studies of the present inventor, it has been found that the lower the light reflectance of the layer C containing ionic copper is, the higher the adhesion between the layer A and the layer B is. In the specified metallized resin film, the layer C contains ionic copper and has a light reflectance of 30% or less. Therefore, in the specified metallized resin film, as shown in Examples described below, the adhesion between the layer A and the layer B tends to be high. In the specified metallized resin film, the adhesion between the layer A and the layer B is high, and therefore embossing is unnecessary in the boundary region between the layer A and the layer B. Thus, in the specified metallized resin film, the layer B can be formed that is strongly adhered to the layer A surface having a low roughness, so that the specified metallized resin film can cope with formation of a circuit having a narrow pitch.

In First Embodiment, for further improvement in the adhesion between the layer A and the layer B, the light reflectance of the layer C may be 28% or less, 25% or less, 20% or less, 19% or less, 18% or less, 17% or less, 16% or less, 15% or less, or 14% or less. The lower limit of the light reflectance of the layer C is not particularly limited, and is, for example, 5% or more.

In First Embodiment, for obtaining the specified metallized resin film having more excellent solder heat resistance, the storage modulus of the polyimide-based resin contained in the layer A may be 0.05 GPa or more, 0.08 GPa or more, or 0.10 GPa or more. From the viewpoint of the handleability of the specified metallized resin film, the storage modulus of the polyimide-based resin contained in the layer A may be 0.50 GPa or less, 0.45 GPa or less, or 0.40 GPa or less.

### Configurations of First Embodiment

Next, the configuration of the metallized resin film (specified metallized resin film) according to First Embodiment will be described with reference to the drawings as appropriate.

FIG. 1 is a sectional view showing an example of the specified metallized resin film. As shown in FIG. 1, a metallized resin film 10 is a laminate including a layer A 11, a layer B 12, and a layer C 13 interposed between the layer A 11 and the layer B 12. The layer C 13 is in contact with both the layer A 11 and the layer B 12. The layer A 11 contains a polyimide-based resin having a storage modulus of 0.02 GPa or more at a temperature of 300° C., and contains a metal oxide particle. The layer C 13 contains ionic copper and has a light reflectance of 30% or less. In the layer A 11, a hole such as a through hole (not illustrated) may be formed. In a case where a hole is formed in the layer A 11, the inside of the hole may be covered with the layer C 13 and the layer B 12. In FIG. 1, the layer B 12 and the layer C 13 are not patterned, but in the metallized resin film according to one or more embodiments of the present invention, the layer B may be patterned, or both the layer B and the layer C may be patterned. Examples of the etching solution for patterning of the layer C include known copper etching solutions (such as an acidic ferric chloride solution).

An electrolytic copper plating layer (not illustrated) may be provided on a main surface 12a of the layer B 12 on the side opposite from the layer C 13 side. An electrolytic copper plating layer is provided on the main surface 12a to obtain a single-sided copper-clad laminate.

The layer C 13 includes, for example, a compound derived from three components of a metal oxide particle, a copper ion, and a polyimide-based resin (compound containing ionic copper). For example, the layer C 13 is strongly adhered to each of the layer A 11 and the layer B 12 by ionic bonding. The layer C 13 is visually observed to be black, and the fact that the layer C 13 contains ionic copper can be confirmed by the analysis method described below.

For easier formation of a circuit having a narrow pitch, the main surface of the layer A 11 on the layer C 13 side may have an arithmetic average roughness Ra of 220 nm or less, 200 nm or less, 170 nm or less, or 150 nm or less. For further improvement in the adhesion between the layer A 11 and the layer B 12, the main surface of the layer A 11 on the layer C 13 side may have an arithmetic average roughness Ra of 10 nm or more, or 50 nm or more. The arithmetic average roughness Ra can be adjusted, for example, by changing at least one of the amount of the metal oxide particle in the layer A 11, the kind (apparent specific gravity, presence or absence of surface treatment, and the like) of the metal oxide particle in the layer A 11, the chemical structure of the polyimide-based resin in the layer A 11, the condition of the desmear treatment described below, and the condition for formation of the layer B 12. The method of measuring the arithmetic average roughness Ra is the same as or similar to the method in Examples described below.

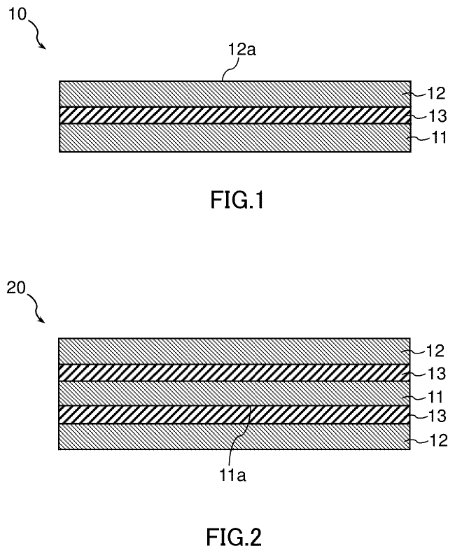

Next, a specified metallized resin film different from the metallized resin film 10 will be described with reference to FIG. 2. Hereinafter, differences from the metallized resin film 10 will be mainly described.

FIG. 2 is a sectional view showing another example of a specified metallized resin film. As shown in FIG. 2, in a metallized resin film 20, a layer C 13 and a layer B 12 are stacked in this order on a main surface 11a of a layer A 11 on the lower side in FIG. 2. That is, in the metallized resin film 20, a layer C 13 and a layer B 12 are stacked in this order on each of both main surfaces of the layer A 11. The metallized resin film 20 includes the layer A 11 having both main surfaces on which a layer C 13 and a layer B 12 are provided, and thus warpage of the metallized resin film 20 is suppressed. An electrolytic copper plating layer (not illustrated) may be provided on each of both main surfaces of the metallized resin film 20. An electrolytic copper plating layer is provided on each of both main surfaces of the metallized resin film 20 to obtain a double-sided copper-clad laminate. For the rest, the metallized resin film 20 is the same as the metallized resin film 10.

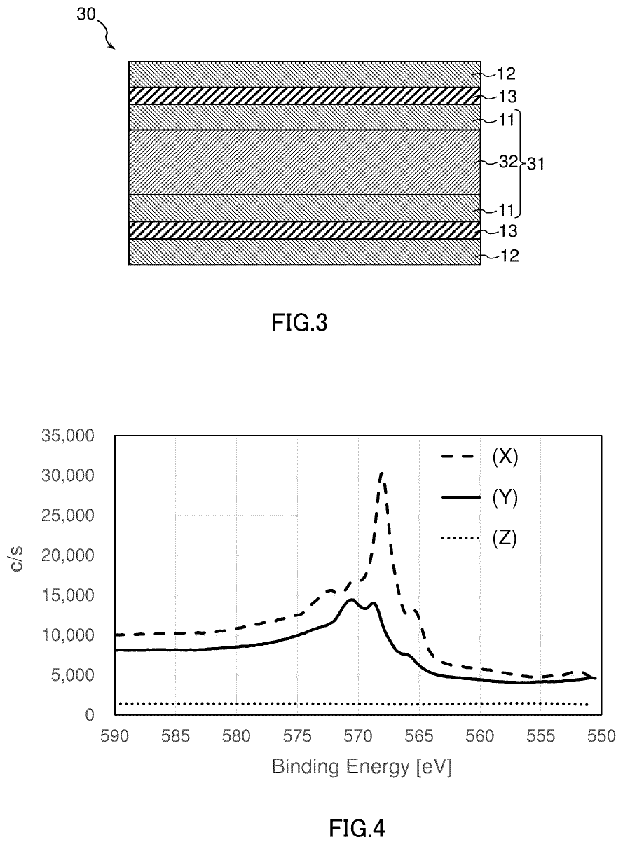

Next, a specified metallized resin film different from the metallized resin film 10 and the metallized resin film 20 will be described with reference to FIG. 3. Hereinafter, differences from the metallized resin film 20 will be mainly described.

FIG. 3 is a sectional view showing another example of a specified metallized resin film. As shown in FIG. 3, a metallized resin film 30 has a structure in which the layer A 11 of the metallized resin film 20 (see FIG. 2) is replaced with a multilayer resin film 31. The multilayer resin film 31 includes a layer D 32 and two layers A 11 sandwiching the layer D 32. That is, in the metallized resin film 30, a layer A 11, a layer C 13, and a layer B 12 are stacked in this order on each of both main surfaces of the layer D 32. The layer D 32 is not particularly limited except that the layer D 32 is an insulating layer different from the layer A 11. Examples of the layer D 32 include a polyimide-based resin layer (more specifically, a non-thermoplastic polyimide layer or the like), a liquid crystal polyester resin layer, a glass epoxy substrate layer, and a glass substrate layer. In the case of using the metallized resin film 30 as a circuit board material of a flexible printed wiring board, the layer D 32 may be a non-thermoplastic polyimide layer, or a non-thermoplastic polyimide layer having a thickness of 5 μm or more and 50 μm or less. In the case of applying the metallized resin film 30 to a printed wiring board or a glass interposer for semiconductor mounting, the layer D 32 may be a glass substrate layer.

An electrolytic copper plating layer (not illustrated) may be provided on each of both main surfaces of the metallized resin film 30. An electrolytic copper plating layer is provided on each of both main surfaces of the metallized resin film 30 to obtain a double-sided copper-clad laminate. The metallized resin film 30 is suitable, for example, as a circuit board material of a flexible printed wiring board. For the rest, the metallized resin film 30 is the same as the metallized resin film 20.

The configuration of the metallized resin film (specified metallized resin film) according to First Embodiment is described above, but the present invention is not limited to the above-described embodiments. For example, the metallized resin film according to one or more embodiments of the present invention may be a metallized resin film having a layer configuration of layer B 12/layer C 13/layer A 11/layer D 32, or may be a metallized resin film having a layer configuration of layer B 12/layer C 13/layer A 11/layer D 32/layer B 12.

### Elements of First Embodiment

Next, Elements of the metallized resin film (specified metallized resin film) according to First Embodiment will be described.

### Layer A

The layer A contains a polyimide-based resin having a storage modulus of 0.02 GPa or more at a temperature of 300° C., and contains a metal oxide particle. The layer A may contain a component other than the polyimide-based resin and the metal oxide particle (another component). Examples of another component include resins other than the polyimide-based resin (other resins), dyes, surfactants, leveling agents, plasticizers, and sensitizers.

For obtaining a specified metallized resin film that is further excellent in solder heat resistance and easily capable of coping with formation of a circuit having a narrow pitch, the content rate of the polyimide-based resin in the layer A may be 50 wt % or more, 60 wt % or more, 70 wt % or more, 80 wt % or more, 90 wt % or more, 95 wt % or more, or 100 wt % with respect to 100 wt % of the resin component contained in the layer A.

For obtaining a specified metallized resin film that is further excellent in solder heat resistance and easily capable of coping with formation of a circuit having a narrow pitch, the total content rate of the polyimide-based resin and the metal oxide particle in the layer A may be 70 wt % or more, 80 wt % or more, 90 wt % or more, 95 wt % or more, or 100 wt % with respect to the total amount of the layer A.

### Polyimide-Based Resin

In the case of applying the specified metallized resin film to a printed wiring board, the polyimide-based resin in the layer A may withstand the temperature of a high-temperature process during processing and the high temperature at the time of component mounting. Therefore, the polyimide-based resin used in the layer A may have a high glass transition temperature, and/or have a high storage modulus at a high temperature. The high glass transition temperature and the high storage modulus at a high temperature enable the adhesion between the layer A and the layer B to be kept high at a high temperature, and as a result, the polyimide-based resin can withstand the temperature of a high-temperature process and the high temperature at the time of component mounting. For ensuring the adhesion between the layer A and the layer B at a high temperature, the polyimide-based resin in the layer A may have a glass transition temperature of 180° C. or more, 210° C. or more, or 230° C. or more. The upper limit of the glass transition temperature of the polyimide-based resin in the layer A is not particularly limited, but is 400° C. or less from the viewpoint of reducing the manufacturing cost.

The polyimide-based resin may have a glass transition temperature and a storage modulus at a high temperature in appropriate ranges, and examples of the polyimide-based resin include polyimides, polyamideimides, polyesterimides, and polyamideimide esters. Among them, polyimides are preferable.

As a result of studies of the present inventor, it has been found that the linear expansion coefficient of the polyimide-based resin used in the layer A affects the adhesion between the layer A and the layer B and, specifically, good adhesion is exhibited in the case of a linear expansion coefficient of 30 ppm/K or more. In the present description, the linear expansion coefficient of the polyimide-based resin is the linear expansion coefficient in the plane direction of the film-shaped polyimide-based resin used in the layer A, and reflects the degree of in-plane orientation of the molecular chains of the polyimide-based resin in the layer A.

The linear expansion coefficient of the polyimide-based resin can be adjusted by the kind of a monomer used in synthesis of the polyimide-based resin. For a decrease in the linear expansion coefficient of the polyimide-based resin, it is effective to use a monomer having a rigid chemical structure and increase the composition ratio of the monomer. If a monomer having a rigid chemical structure is used and the composition ratio of the monomer is increased, polyimide molecular chains are oriented in the plane direction at the time of processing into a film shape. For an increase in the linear expansion coefficient of the polyimide-based resin, it is effective to use a monomer having a flexible chemical structure and increase the composition ratio of the monomer.

For further improvement in the adhesion between the layer A and the layer B, the polyimide-based resin may have a linear expansion coefficient of 30 ppm/K or more, more than 30 ppm/K, 35 ppm/K or more, 40 ppm/K or more, 45 ppm/K or more, or 50 ppm/K or more. Meanwhile, for ensuring the heat resistance and the dimensional stability, the polyimide-based resin may have a linear expansion coefficient of 100 ppm/K or less, or 80 ppm/K or less.

Hereinafter, a case will be described in which a polyimide is used as the polyimide-based resin. Examples of a raw material monomer (a diamine and an acid dianhydride) of the polyimide include monomers having a flexible chemical structure (skeleton) and monomers having a rigid chemical structure (skeleton), and desired physical properties can be realized by appropriately selecting these monomers and further adjusting the blending ratio.

Examples of the diamine having a flexible skeleton include 4,4′-oxydianiline (hereinafter, sometimes described as “ODA”), 2,2-bis[4-(4-aminophenoxy)phenyl]propane (hereinafter, sometimes described as “BAPP”), 1,3-bis(4-aminophenoxy)benzene (hereinafter, sometimes described as “TPE-R”), 3,3′-oxydianiline, 3,4′-oxydianiline, bis[4-(4-aminophenoxy)phenyl]sulfone, bis[4-(3-aminophenoxy)phenyl]sulfone, 3,4′-diaminodiphenyl ether, 3,3′-diaminodiphenyl ether, 4,4′-diaminobenzophenone, 3,4′-diaminobenzophenone, 3,3′-diaminobenzophenone, 1,3-bis(3-aminophenoxy)benzene, 1,4-bis(3-aminophenoxy)benzene, 1,4-bis(4-aminophenoxy)benzene, 2,2-bis[4-(3-aminophenoxy)phenyl] propane, 4,4′-bis(4-aminophenoxy)biphenyl, and 4,4′-bis(3-aminophenoxy)biphenyl.

Meanwhile, examples of the diamine having a rigid skeleton include p-phenylenediamine (hereinafter, sometimes described as “PDA”), 2,2′-dimethylbenzidine (hereinafter, sometimes described as “m-TB”), 2,2′-bis(trifluoromethyl)benzidine (hereinafter, sometimes described as “TFMB”), 1,3-diaminobenzene, 1,2-diaminobenzene, benzidine, 3,3′-dichlorobenzidine, 3,3′-dimethylbenzidine, 3,3′-dimethoxybenzidine, 2,2′-dimethoxybenzidine, 1,5-diaminonaphthalene, 4,4′-diaminobenzanilide, 3,4′-diaminobenzanilide, and 3,3′-diaminobenzanilide.

The diamine having a flexible skeleton may be one or more selected from the group consisting of ODA, BAPP, and TPE-R, or one or more selected from the group consisting of ODA and TPE-R, from the viewpoint of easy availability and easy control of thermal characteristics. The diamine having a rigid skeleton may be one or more selected from the group consisting of PDA, m-TB, and TFMB, or one or more selected from the group consisting of PDA and m-TB, from the viewpoint of easy availability and easy control of thermal characteristics. These diamines may be used singly or as a mixture (in combination) of two or more kinds thereof.

Examples of the tetracarboxylic dianhydride having a flexible skeleton include 4,4′-oxydiphthalic anhydride (hereinafter, sometimes described as “ODPA”), 3,3′, 4,4′-benzophenonetetracarboxylic dianhydride, and 3,4′-oxydiphthalic anhydride.

Meanwhile, examples of the tetracarboxylic dianhydride having a rigid skeleton include 3,3′,4,4′-biphenyltetracarboxylic dianhydride (hereinafter, sometimes described as “BPDA”), pyromellitic dianhydride (hereinafter, sometimes described as “PMDA”), 2,3,6,7-naphthalenetetracarboxylic dianhydride, 1,2,5,6-naphthalenetetracarboxylic dianhydride, and 3,4,9,10-perylenetetracarboxylic dianhydride.

The tetracarboxylic dianhydride having a flexible skeleton may be ODPA from the viewpoint of easy availability and easy control of thermal characteristics. The tetracarboxylic dianhydride having a rigid skeleton may be one or more selected from the group consisting of BPDA and PMDA, or BPDA, from the viewpoint of easy availability and easy control of thermal characteristics. These tetracarboxylic dianhydrides may be used singly or as a mixture (in combination) of two or more kinds thereof.

For obtaining a specified metallized resin film that is further excellent in solder heat resistance and easily capable of coping with formation of a circuit having a narrow pitch, the polyimide contained in the layer A may have one or more diamine residues selected from the group consisting of a TFMB residue, an ODA residue, a TPE-R residue, a BAPP residue, an m-TB residue, and a PDA residue and one or more tetracarboxylic dianhydride residues selected from the group consisting of an ODPA residue, a BPDA residue, and a PMDA residue, or have one or more diamine residues selected from the group consisting of an ODA residue, a TPE-R residue, an m-TB residue, and a PDA residue and one or more tetracarboxylic dianhydride residues selected from the group consisting of an ODPA residue, a BPDA residue, and a PMDA residue.

For obtaining a specified metallized resin film that is further excellent in solder heat resistance and easily capable of coping with formation of a circuit having a narrow pitch, the total content rate of an ODA residue, a TPE-R residue, an m-TB residue, and a PDA residue in the polyimide contained in the layer A may be 70 mol % or more and 100 mol % or less, 80 mol % or more and 100 mol % or less, 90 mol % or more and 100 mol % or less, or 100 mol % with respect to all of the diamine residues constituting the polyimide.

For obtaining a specified metallized resin film that is further excellent in solder heat resistance and easily capable of coping with formation of a circuit having a narrow pitch, the total content rate of an ODPA residue, a BPDA residue, and a PMDA residue in the polyimide contained in the layer A may be 70 mol % or more and 100 mol % or less, 80 mol % or more and 100 mol % or less, 90 mol % or more and 100 mol % or less, or 100 mol % with respect to all of the acid dianhydride residues constituting the polyimide.

The polyimide contained in the layer A is obtained by imidizing the polyamic acid as a precursor of the polyimide. As the method of manufacturing (synthesizing) the polyamic acid, any of known methods and combinations thereof can be used. In manufacture of the polyamic acid, normally, a diamine and a tetracarboxylic dianhydride are reacted in an organic solvent. The substance amount of a diamine and the substance amount of a tetracarboxylic dianhydride in the reaction may be substantially the same. When the polyamic acid is synthesized using a diamine and a tetracarboxylic dianhydride, the desired polyamic acid (polymer of a diamine and a tetracarboxylic dianhydride) can be obtained by adjusting the substance amount of each diamine and the substance amount of each tetracarboxylic dianhydride. The molar fraction of each residue in the polyamic acid is equal to, for example, the molar fraction of each monomer (each of a diamine and a tetracarboxylic dianhydride) used for synthesis of the polyamic acid. The temperature condition for the reaction of a diamine and a tetracarboxylic dianhydride, that is, the synthesis reaction of the polyamic acid is not particularly limited, and is, for example, in the range of 10° C. or more and 150° C. or less. The time for the synthesis reaction of the polyamic acid is, for example, in the range of 10 minutes or more and 30 hours or less. In the present embodiment, any method of adding a monomer may be used for manufacture of the polyamic acid.

For obtaining the polyimide contained in the layer A, a method may be adopted in which the polyimide is obtained from a polyamic acid solution containing the polyamic acid and an organic solvent. Examples of the organic solvent usable in the polyamic acid solution include urea-based solvents such as tetramethylurea and N,N-dimethylethylurea; sulfoxide-based solvents such as dimethyl sulfoxide; sulfone-based solvents such as diphenyl sulfone and tetramethyl sulfone; amide-based solvents such as N,N-dimethylacetamide, N,N-dimethylformamide (hereinafter, sometimes described as “DMF”), N,N-diethylacetamide, N-methyl-2-pyrrolidone, and hexamethylphosphoric triamide; ester-based solvents such as γ-butyrolactone; alkyl halide-based solvents such as chloroform and methylene chloride; aromatic hydrocarbon-based solvents such as benzene and toluene; phenol-based solvents such as phenol and cresol; ketone-based solvents such as cyclopentanone; and ether-based solvents such as tetrahydrofuran, 1,3-dioxolane, 1,4-dioxane, dimethyl ether, diethyl ether, diethylene glycol diethyl ether, diethylene glycol dimethyl ether, and p-cresol methyl ether. These solvents are normally used singly, and if necessary, may be appropriately used in combination of two or more kinds thereof. In the case of obtaining the polyamic acid with the above-described synthesis method, the reaction solution (solution after reaction) itself may be a polyamic acid solution. In this case, the organic solvent in the polyamic acid solution is the organic solvent used in the reaction in the synthesis method. Alternatively, the solid polyamic acid obtained by removing the solvent from the reaction solution may be dissolved in an organic solvent to prepare a polyamic acid solution. The solid content concentration in the polyamic acid solution is not particularly limited, and if the solid content concentration is in the range of 5 wt % or more and 35 wt % or less, a polyamic acid is obtained such that the resulting polyimide has a sufficient mechanical strength.

### Metal Oxide Particle

Examples of the metal oxide particle include metal oxide particles containing, as a main component, silica, alumina, titania, copper oxide, iron oxide, zirconia, magnesium oxide, barium oxide, or the like. For obtaining a specified metallized resin film that is further excellent in solder heat resistance and easily capable of coping with formation of a circuit having a narrow pitch, the metal oxide particle is a silica particle. As the metal oxide particle, metal oxide particles are usable such as spherical or heteromorphic metal oxide particles in which primary particles exist independently, and fumed metal oxide particles having a constituent unit that is a structure in which primary particles are aggregated.

The metal oxide particle in the layer A constitutes the layer A together with the polyimide-based resin, but for firmer adhesion between the layer A and the layer B, the metal oxide particle may be adhered to the polyimide-based resin firmly. For improvement in adhesion between the metal oxide particle and the polyimide-based resin, the metal oxide particle may have a structurally complicated shape. The metal oxide particle having a structurally complicated shape has a large interaction with the polyimide-based resin, and therefore such a metal oxide particle can be firmly adhered to the polyimide-based resin, and has a large specific surface area. The metal oxide particle having a structurally complicated shape may be a fumed metal oxide particle, or a fumed silica particle.

The fumed metal oxide particle may be a metal oxide particle obtained by gas phase synthesis. The fumed metal oxide particle obtained by gas phase synthesis has a constituent unit that is a structure in which primary particles are aggregated (for example, an aggregate structure like a bunch of grapes) due to the characteristics of the production method. In other words, the fumed metal oxide particle may have a constituent unit that is a structure in which primary particles are aggregated.

The fumed metal oxide particle is partially dissolved in the vicinity of its surface by a desmear treatment described below, but for easier formation of a circuit having a narrow pitch, the layer A may have a not too large surface roughness even if the fumed metal oxide particle is dissolved in the vicinity of its surface. For maintaining the surface roughness of the layer A within an appropriate range, the fumed metal oxide particle may have a primary particle size of 5 nm or more and 1000 nm or less, 5 nm or more and 100 nm or less, 5 nm or more and 50 nm or less, or 10 nm or more and 20 nm or less. For maintaining the surface roughness of the layer A within an appropriate range, the fumed metal oxide particle may have a specific surface area of 30 m²/g or more and 400 m²/g or less, or 100 m²/g or more and 250 m²/g or less.

The suitable blending ratio between the fumed metal oxide particle and the polyimide-based resin depends on the apparent specific gravity of the fumed metal oxide particle. The smaller the apparent specific gravity of the fumed metal oxide particle is, the larger a void in the structure of the fumed metal oxide particle is, and the void can be filled using a large amount of the polyimide-based resin. Meanwhile, the larger the apparent specific gravity of the fumed metal oxide particle is, the smaller the amount of the polyimide-based resin used to fill a void in the structure of the fumed metal oxide particle can be. The apparent specific gravity of the fumed metal oxide particle can be measured with a method in accordance with ISO 787/XI.

For improvement in adhesion between the layer A and the layer B by setting the blending ratio between the fumed metal oxide particle and the polyimide-based resin within an appropriate range, the fumed metal oxide particle may have an apparent specific gravity of 20 g/L or more and 250 g/L or less, 50 g/L or more and 250 g/L or less, 60 g/L or more and 250 g/L or less, 70 g/L or more and 250 g/L or less, or 70 g/L or more and 220 g/L or less.

The fumed metal oxide particle may be subjected to various surface treatments such as a hydrophobic treatment. For maintaining the surface roughness of the layer A in an appropriate range, the surface of the fumed metal oxide particle may be subjected to a hydrophobic treatment.

Commercially available products of the fumed metal oxide particle are available from, for example, NIPPON AEROSIL CO., LTD., Wacker Asahikasei Silicone Co., Ltd., and Cabot Corporation. Among them, as the fumed metal oxide particle (fumed silica particle) manufactured by NIPPON AEROSIL CO., LTD., AEROSIL R974, E9200, R9200, and the like may be used, and among them, AEROSIL R9200 (apparent specific gravity: 200 g/L) and AEROSIL E9200 (apparent specific gravity: 80 to 120 g/L), which have a relatively high apparent specific gravity, may be used. In addition, AEROSIL NX130, RY200S, R976, NAX50, NX90G, NX90S, RX200, RX300, R812, R812S, and the like may be used as fumed silica particles manufactured by NIPPON AEROSIL CO., LTD. having a relatively low apparent specific gravity.

In a case where the fumed metal oxide particle has an apparent specific gravity of 20 g/L or more and less than 70 g/L, for firmer adhesion between the layer A and the layer B, the amount of the fumed metal oxide particle in the layer A may be 15 parts by weight or more and 80 parts by weight or less, or 20 parts by weight or more and 70 parts by weight or less with respect to 100 parts by weight of the polyimide-based resin in the layer A.

In a case where the fumed metal oxide particle has an apparent specific gravity of 70 g/L or more and 250 g/L or less, for firmer adhesion between the layer A and the layer B, the amount of the fumed metal oxide particle in the layer A may be 10 parts by weight or more and 130 parts by weight or less, 15 parts by weight or more and 120 parts by weight or less, 20 parts by weight or more and 100 parts by weight or less, 30 parts by weight or more and 100 parts by weight or less, or 30 parts by weight or more and 90 parts by weight or less with respect to 100 parts by weight of the polyimide-based resin in the layer A. For still firmer adhesion between the layer A and the layer B, the fumed metal oxide particle may have an apparent specific gravity of 70 g/L or more and 220 g/L or less, and the amount of the fumed metal oxide particle in the layer A may be 20 parts by weight or more and 90 parts by weight or less, 30 parts by weight or more and 90 parts by weight or less, 30 parts by weight or more and 80 parts by weight or less, 30 parts by weight or more and 70 parts by weight or less, or 30 parts by weight or more and 60 parts by weight or less with respect to 100 parts by weight of the polyimide-based resin in the layer A.

As the metal oxide particle contained in the layer A, spherical or heteromorphic metal oxide particles in which primary particles exist independently can be used in addition to the fumed metal oxide particle. Specific examples of the spherical or heteromorphic metal oxide particles include ADMANANO, ADMAFINE, and ADMAFUSE manufactured by ADMATECHS COMPANY LIMITED.

### Method of Forming Layer A

As a method of forming the layer A, an appropriate method can be selected according to the characteristics of the polyimide-based resin. For example, in a case where the polyimide-based resin is solvent-soluble, a method is used in which metal oxide particles are dispersed in an organic solvent, the obtained particle dispersion is added to a solution of the polyimide-based resin to obtain a layer A-forming dispersion, and then the layer A-forming dispersion is applied onto an appropriate support and dried to obtain a layer A (hereinafter, sometimes described as a “first method”).

In a case where the polyimide-based resin is thermoplastic, a method is used, for example, in which a mixture of the polyimide-based resin and a metal oxide particle is kneaded at a temperature equal to or higher than the melting point of the polyimide-based resin to obtain a layer A-forming resin bulk, and then the layer A-forming resin bulk is molded into a film shape while heated and pressurized or with a method using a melt extruder to obtain a layer A (hereinafter, sometimes described as a “second method”).

For firmer adhesion between the layer A and the layer B, the metal oxide particles may be uniformly dispersed, and particularly in the case of using fumed metal oxide particles as the metal oxide particles, the fumed metal oxide particles may be dispersed to a constituent unit including a structure in which primary particles are aggregated and fused into a rosary shape (aggregated particles).

In the first method, examples of the method of dispersing the metal oxide particles include methods using a disperser, a homogenizer, a planetary mixer, a bead mill, a rotation-revolution mixer, a roll, a kneader, a high-pressure disperser, an ultrasonic wave, or the like. In the second method, examples of the method of dispersing the metal oxide particles include methods using an apparatus such as a screw extruder or a melt kneader.

In a case where the polyimide-based resin in the layer A is a polyimide, a third method can also be used in which the above-described polyamic acid solution and a particle dispersion in which metal oxide particles are dispersed are mixed to obtain a layer A-forming dispersion, then the layer A-forming dispersion is applied onto an appropriate support, and the resulting coating film is heated (dried and imidized) to obtain a layer A.

In the third method, examples of a suitably used support to which the layer A-forming dispersion is applied include a glass plate, an aluminum foil, an endless stainless belt, a stainless drum, and a resin film (such as a non-thermoplastic polyimide film). The drying temperature for the coating film is, for example, 50° C. or more and 200° C. or less. The drying time for drying of the coating film is, for example, 1 minute or more and 100 minutes or less. The heating conditions at the time of imidization are appropriately set according to the ultimately obtained film thickness, the production speed, and the like. As the heating conditions at the time of imidization, the maximum temperature is, for example, 370° C. or more and 470° C. or less, and the heating time at the maximum temperature is, for example, 5 seconds or more and 180 seconds or less. The temperature may be held at any temperature for any period of time until reaching the maximum temperature.

For obtaining a specified metallized resin film that is further excellent in solder heat resistance, easily capable of coping with formation of a circuit having a narrow pitch, and can be formed into a thin film, the layer A may have a thickness of 1 μm or more and 50 μm or less, or 2 μm or more and 20 μm or less.

### Layer B

The layer B is an electroless copper plating layer. The electroless copper plating layer obtained by electroless copper plating can be thinner than a general copper foil. The layer B may have a thickness of 0.01 μm or more and 10.00 μm or less, 0.10 μm or more and 2.00 μm or less, or 0.20 μm or more and 1.00 μm or less.

The method of forming the layer B may be a reduction-type electroless copper plating method using a chemical reaction. As the electroless copper plating process, solution processes available from plating solution manufacturers can be used. The layer A surface may be subject to a desmear treatment before electroless copper plating. The desmear treatment is originally performed for the purpose of removing a smear generated on a copper surface in a through-hole forming step or a laser via forming step.

### Layer C

The layer C is an adhesion layer for adhesion between the layer A and the layer B. The layer C contains ionic copper and has a light reflectance of 30% or less. The light reflectance can be adjusted, for example, by changing at least one of the amount of the metal oxide particle in the layer A, the kind (apparent specific gravity, presence or absence of surface treatment, and the like) of the metal oxide particle in the layer A, the chemical structure of the polyimide-based resin in the layer A, the condition of the desmear treatment described below, and the condition for formation of the layer B.

The layer C includes, for example, a compound derived from three components of a metal oxide particle, a copper ion, and a polyimide-based resin (compound containing ionic copper). For firmer adhesion between the layer A and the layer B, the layer C may have a thickness of 1 nm or more and 20 nm or less, or 1 nm or more and 10 nm or less. Examples of a method of confirming the layer C include a method using SAICAS described in Examples described below.

Whether the layer C contains ionic copper can be confirmed by analyzing the layer C using X-ray photoelectron spectroscopy (XPS). Specifically, in a CuLMM spectrum in XPS, if the main peak observed in the binding energy range of 575 to 565 eV has a binding energy in the range of 573 to 568.5 eV, the main state of the copper element is copper having ionicity (ionic copper), and it can be determined that “ionic copper is present in the layer C”. The peak indicating metallic copper has a binding energy of 568.0 eV, and is shown at a position different from that of ionic copper.

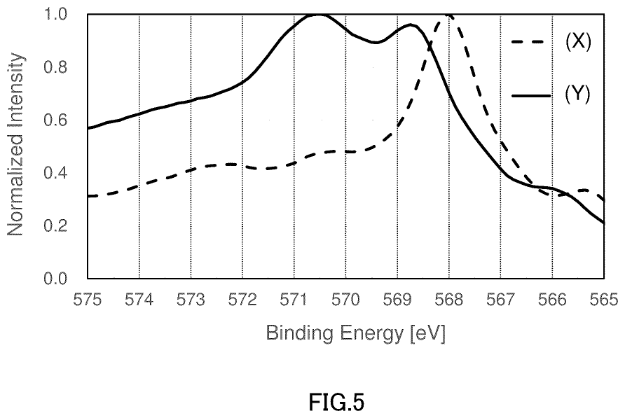

The XPS analysis will be specifically described with reference to FIGS. 4 and 5. FIG. 4 shows an example of spectrum data obtained by analyzing a metallized resin film by XPS. FIG. 5 is a graph obtained by normalizing the spectral intensity in FIG. 4.

In FIG. 4, the following three spectra are plotted.
Spectrum (X): XPS spectrum of layer B
Spectrum (Y): XPS spectrum of layer C
Spectrum (Z): XPS spectrum of layer A

From FIGS. 4 and 5, it can be seen that the spectrum (Y) has a main peak observed at 570.5eV. The peak at 570.5 eV is a peak indicating ionic copper, and therefore it can be determined that the analyzed layer C contains ionic copper.

Meanwhile, from FIGS. 4 and 5, it can be seen that the spectrum (X) has a main peak observed at 568.0 eV. The peak at 568.0 eV is a peak indicating metallic copper, and therefore it can be determined that the copper element in the analyzed layer B is metallic copper. From FIG. 4, the spectrum (Z) has no clear peak observed. Therefore, it can be determined that a copper element is absent in the layer A portion.

For obtaining a specified metallized resin film that is further excellent in solder heat resistance and further easily capable of coping with formation of a circuit having a narrow pitch, the specified metallized resin film may satisfy the following condition 1, satisfy the following condition 2, satisfy the following condition 3, or satisfy the following condition 4.
Condition 1: The polyimide-based resin contained in the layer A has one or more diamine residues selected from the group consisting of an ODA residue, a TPE-R residue, an m-TB residue, and a PDA residue and one or more tetracarboxylic dianhydride residues selected from the group consisting of an ODPA residue, a BPDA residue, and a PMDA residue.
Condition 2: The condition 1 is satisfied, and the metal oxide particle contained in the layer A is a fumed silica particle.
Condition 3: The condition 2 is satisfied, and the fumed silica particle has an apparent specific gravity of 70 g/L or more and 220 g/L or less.
Condition 4: The condition 3 is satisfied, and the amount of the fumed silica particle in the layer A is 20 parts by weight or more and 90 parts by weight or less with respect to 100 parts by weight of the polyimide-based resin in the layer A.

### SECOND EMBODIMENT: METHOD FOR MANUFACTURING METALLIZED RESIN FILM

Next, a method for manufacturing a metallized resin film according to Second Embodiment of the present invention will be described. The method for manufacturing according to Second Embodiment of the present invention is a suitable method for manufacturing the metallized resin film (specified metallized resin film) according to First Embodiment of the present invention. In the following description, description of contents overlapping with the contents of First Embodiment may be omitted.

The method for manufacturing a metallized resin film according to Second Embodiment is a method for manufacturing a metallized resin film in which an electroless copper plating layer is formed on a desmear-treated resin composition layer. The resin composition layer is the layer A of the above-described specified metallized resin film. The electroless copper plating layer is the layer B of the above-described specified metallized resin film.

In Second Embodiment, the term “desmear treatment” refers to, for example, a treatment including the following three treatment steps (swelling step, roughening step, and neutralization step).
Swelling step: Step of swelling layer A surface
Roughening step: Step of roughening layer A surface using alkaline aqueous solution containing oxidizing agent such as permanganate
Neutralization step: Step of treating layer A surface with acid solution

The condition of the desmear treatment is not particularly limited, and for example, the condition of the desmear treatment described in JP 2011-40727 A can be adopted. For firmer adhesion between the layer A and the layer B, the treatment time in each of the above steps of the desmear treatment may be 30 seconds or more and 20 minutes or less, or 1 minute or more and 15 minutes or less.

The method of forming an electroless copper plating layer is also not particularly limited, and for example, a reduction-type electroless copper plating method using a chemical reaction can be adopted. As the treatment condition of the reduction-type electroless copper plating method, the conditions of the solution processes available from plating solution manufacturers can be adopted, and for example, the condition of the electroless copper plating process described in JP 2011-40727 A can be adopted.

The layer C is formed between the layer A and the layer B with the method for manufacturing a metallized resin film according to Second Embodiment. The reason for this is presumed as follows.

The layer A surface is desmear-treated to form an ionic functional group on the polyimide-based resin present on the layer A surface. Next, the electroless copper plating treatment causes an interaction among the ionic functional group, a copper ion in an electroless copper plating bath, and a metal oxide particle to generate a compound derived from three components of the metal oxide particle, the copper ion, and the polyimide-based resin (compound containing ionic copper) in a layer form on the layer A surface, and thus the layer C is formed. The ionic copper in the formed layer C is ionically bonded to the ionic functional group present on the layer A surface and an anion site present on the layer B surface, and thus the layer A and the layer B are firmly adhered to each other.

### THIRD EMBODIMENT: PRINTED WIRING BOARD

Next, a printed wiring board according to Third Embodiment of the present invention will be described. The printed wiring board according to Third Embodiment of the present invention is a printed wiring board including the metallized resin film (specified metallized resin film) according to First Embodiment of the present invention. In the following description, description of contents overlapping with the contents of First Embodiment may be omitted. The term “printed wiring board including the specified metallized resin film” refers to both a “printed wiring board made of the specified metallized resin film” and a “printed wiring board including the specified metallized resin film and another member”.

The printed wiring board according to Third Embodiment includes the specified metallized resin film, and therefore the printed wiring board is excellent in solder heat resistance and can cope with formation of a circuit having a narrow pitch. The printed wiring board according to Third Embodiment includes the specified metallized resin film, and therefore the flexibility of the printed wiring board is high. Therefore, the printed wiring board according to Third Embodiment can be applied to a flexible printed wiring board, a multilayer flexible printed wiring board, a rigid flex circuit board, a chip-on-film circuit board, a build-up multilayer circuit board, and the like.

The printed wiring board according to Third Embodiment may have a high peel strength between the layer A and the layer B from the viewpoint of reliability required for use as a printed wiring board. Specifically, the peel strength between the layer A and the layer B may be 5 N/cm or more, 6 N/cm or more, or 9 N/cm or more.

### FOURTH EMBODIMENT: CURRENT COLLECTOR FILM FOR LITHIUM ION BATTERIES

Next, a current collector film for lithium ion batteries according to Fourth Embodiment of the present invention will be described. The current collector film for lithium ion batteries according to Fourth Embodiment of the present invention is a current collector film for lithium ion batteries that includes the metallized resin film (specified metallized resin film) according to First Embodiment of the present invention. In the following description, description of contents overlapping with the contents of First Embodiment may be omitted. The term “current collector film for lithium ion batteries that includes the specified metallized resin film” refers to both a “current collector film for lithium ion batteries that is made of the specified metallized resin film” and a “current collector film for lithium ion batteries that includes the specified metallized resin film and another member”.

Lithium ion batteries have characteristics of a small size and a high voltage, that is, a high energy density, but are required to further improve in energy density. Lithium ion batteries generally have a negative electrode in which a carbon-based material or an alloy-based material is used as a negative electrode active material, and in manufacture of a negative electrode, the negative electrode active material is processed into a slurry form. Then, the slurry is applied onto a surface of a copper foil serving as a current collector and dried to form a negative electrode active material layer, and thus a negative electrode is obtained. A copper foil serving as a current collector is composed of a copper element, and therefore has a high density as its property, and thus is disadvantageous from the viewpoint of the energy density of a lithium ion battery. Therefore, if the specified metallized resin film is used instead of a conventional copper foil current collector, for example, the weight of the current collector can be reduced even if the current collector has the same thickness and the same area as the conventional copper foil current collector. That is, the energy density of a lithium ion battery can be improved by using the specified metallized resin film instead of a usually used copper foil current collector.

### ANOTHER USE

As described above, examples of the use of the specified metallized resin film include the use in the printed wiring board and the use in the current collector film for lithium ion batteries, but the use of the specified metallized resin film is not limited thereto. For example, the specified metallized resin film may be used as an electrode film for touch panels. In a copper mesh electrode film for touch panels, a metal circuit is formed on an insulating resin film, and the metal circuit is required to be firmly adhered to the insulating resin film and to have a black surface on a side in contact with the resin film and have a low light reflectance. The specified metallized resin film achieves high adhesion between the layer A and the layer B and a low light reflectance of the layer C, and therefore is suitable for an electrode film for touch panels.

The specified metallized resin film may be used as an electromagnetic wave shielding film. The specified metallized resin film has high adhesion between the layer A and the layer B, and therefore the specified metallized resin film can improve the reliability of electromagnetic wave shielding performance, and is suitable as an electromagnetic wave shielding film having an excellent lightweight property.

### EXAMPLES

Hereinafter, one or more embodiments of the present invention will be specifically described with reference to Examples, but the present invention is not limited to these Examples.

### Preparation of Polyamic Acid Solution

First, a method of preparing a polyamic acid solution used in Examples and Comparative Examples will be described. In the following, compounds and reagents are represented by the following abbreviations. A polyamic acid solution was prepared in a nitrogen atmosphere at a temperature of 25° C. in Examples and Comparative Examples.
DMF: N,N-dimethylformamide
TPE-R: 1,3-Bis(4-aminophenoxy)benzene
m-TB: 2,2′-Dimethylbenzidine
ODA: 4,4′-Oxydianiline
PDA: p-Phenylenediamine
BPDA: 3,3′,4,4′-Biphenyltetracarboxylic dianhydride
PMDA: Pyromellitic dianhydride
ODPA: 4,4′-Oxydiphthalic anhydride
BPADA: 4,4′-(4,4′-Isopropylidenediphenoxy)bis(phthalic anhydride)
KF-8010: Diamine represented by the following general formula (3) (trade name: KF-8010, functional group equivalent: 430 g/mol, m in the general formula (3) represents an integer of 3 to 12) manufactured by Shin-Etsu Chemical Co., Ltd.

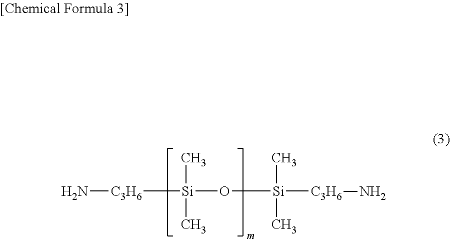

### Preparation of Polyamic Acid Solution PA1

To a glass flask having a volume of 2000 mL, 322.3 g of DMF and 33.9 g of TPE-R were added. Next, while the flask contents were stirred in a nitrogen atmosphere, 33.6 g of BPDA was added in the flask, and the flask contents were stirred for 1 hour. Subsequently, the flask contents were continuously stirred while a BPDA solution prepared separately (solvent obtained by dissolving 0.51 g of BPDA in 9.7 g of DMF) was added in the flask for a predetermined time at an addition rate such that the viscosity of the flask contents did not rapidly increase. At the time when the viscosity of the flask contents at a temperature of 23° C. reached 1000 poises, the addition of the BPDA solution and the stirring of the flask contents were stopped, and thus a polyamic acid solution PA1 was obtained.

### Preparation of Polyamic Acid Solution PA2

To a glass flask having a volume of 2000 mL, 321.8 g of DMF, 1.3 g of m-TB, and 33.7 g of TPE-R were added. Next, while the flask contents were stirred in a nitrogen atmosphere, 7.9 g of PMDA and 24.5 g of BPDA were added in the flask, and then the flask contents were stirred for 1 hour. Subsequently, the flask contents were continuously stirred while a BPDA solution prepared separately (solvent obtained by dissolving 0.54 g of BPDA in 10.7 g of DMF) was added in the flask for a predetermined time at an addition rate such that the viscosity of the flask contents did not rapidly increase. At the time when the viscosity of the flask contents at a temperature of 23° C. reached 1000 poises, the addition of the BPDA solution and the stirring of the flask contents were stopped, and thus a polyamic acid solution PA2 was obtained.

### Preparation of Polyamic Acid Solution PA3

To a glass flask having a volume of 2000 mL, 319.0 g of DMF, 14.6 g of ODA, and 7.9 g of PDA were added. Next, while the flask contents were stirred in a nitrogen atmosphere, 44.7 g of ODPA was added in the flask, and then the flask contents were stirred for 1 hour. Subsequently, the flask contents were continuously stirred while an ODPA solution prepared separately (solvent obtained by dissolving 0.68 g of ODPA in 12.9 g of DMF) was added in the flask for a predetermined time at an addition rate such that the viscosity of the flask contents did not rapidly increase. At the time when the viscosity of the flask contents at a temperature of 23° C. reached 1000 poises, the addition of the ODPA solution and the stirring of the flask contents were stopped, and thus a polyamic acid solution PA3 was obtained.

### Preparation of Polyamic Acid Solution PA4

To a glass flask having a volume of 2000 mL, 320.9 g of DMF, 10.4 g of ODA, and 18.7 g of KF-8010 were added. Next, while the flask contents were stirred in a nitrogen atmosphere, 38.1 g of BPADA was added in the flask, and then the flask contents were stirred for 1 hour. Subsequently, the flask contents were continuously stirred while a BPADA solution prepared separately (solvent obtained by dissolving 0.58 g of BPADA in 11.0 g of DMF) was added in the flask for a predetermined time at an addition rate such that the viscosity of the flask contents did not rapidly increase. At the time when the viscosity of the flask contents at a temperature of 23° C. reached 1000 poises, the addition of the BPADA solution and the stirring of the flask contents were stopped, and thus a polyamic acid solution PA4 was obtained.

Table 1 shows, for each of the polyamic acid solutions PA1 to PA4, the kind and the molar ratio of the used diamine, the kind and the molar ratio of the used acid dianhydride, and the storage modulus at a temperature of 300° C., the Tg (glass transition temperature), and the CTE (linear expansion coefficient) of the polyimide (imidized product of the polyamic acid) obtained using each of the polyamic acid solutions PA1 to PA4. In all of the polyamic acid solutions PA1 to PA4, the molar fraction of each residue in the polyamic acid contained in the prepared polyamic acid solution was equal to the molar fraction of each monomer (each of the diamine and the acid dianhydride) used. The “Storage modulus”, the “Tg”, and the “CTE” in Table 1 were measured with the following methods.

### Storage Modulus and Tg

### Production of Film for Measurement

The polyamic acid solution (specifically, any one of the polyamic acid solutions PA1 to PA4) obtained in the above procedure was applied to an aluminum foil, and then heated at a temperature of 120° C. for 360 seconds, at a temperature of 200° C. for 60 seconds, at a temperature of 350° C. for 200 seconds, and at a temperature of 450° C. for 30 seconds sequentially to perform imidization. Next, the aluminum foil was dissolved and removed using an acid etching solution (ferric chloride solution) to obtain a film for measurement including the polyimide.

From the film obtained in the above procedure, the polyimide film was sampled into a size of 9 mm in width and 50 mm in length and used as a sample, and the storage modulus and the Tg were measured using a dynamic viscoelasticity measuring apparatus (“DMS6100” manufactured by Seiko Instruments Inc.). Specifically, the storage modulus of the sample was measured under the following measurement conditions using the dynamic viscoelasticity measuring apparatus, and the value of the storage modulus at a temperature of 300° C. was read. From a curve showing the relationship between the storage modulus and the temperature obtained under the following measurement conditions, the temperature at the inflection point was taken as the glass transition temperature (Tg).

### Measurement Conditions of Storage Modulus and Tg

Measurement mode: Tension
Distance between grippers: 20 mm
Frequency: 5 Hz
Measurement temperature: 20° C. to 400° C.
Temperature rise rate: 3° C./min
Strain amplitude: 10 μm
Minimum tension: 100 mN
Initial force amplitude value: 100 mN

### Linear Expansion Coefficient (CTE)

From the film for measurement used in the measurement of the storage modulus and the Tg, the polyimide film was sampled into a size of 3 mm in width and 10 mm in length and used as a sample, and the CTE was measured using a thermomechanical analyzer (“TMA120C” manufactured by Seiko Instruments Inc.) under the condition of a load of 3 g. Specifically, by using the thermomechanical analyzer, the sample was heated from 10° C. to 260° C. under a condition of a temperature rise rate of 10° C./min, and then cooled to 10° C. at a temperature decrease rate of 40° C./min. Subsequently, the sample was heated again to 260° C. under the condition of a temperature rise rate of 10° C./min, and the average linear expansion coefficient at 100° C. to 200° C. during the second temperature rise was taken as the CTE.

TABLE 1

| Polyamic | Diamine | | Acid dianhydride | | Storage | | |
|---|---|---|---|---|---|---|---|
| acid | | Molar | | Molar | modulus | Tg | CTE |
| solution | Kind | ratio | Kind | ratio | [GPa] | [° C.] | [ppm/K] |
| PA1 | Only TPE-R | | Only BPDA | | 0.38 | 219 | 54 |
| PA2 | m-TB/TPE-R | 5/95 | BPDA/PMDA | 70/30 | 0.13 | 215 | 36 |

| | | | | | | |
|---|---|---|---|---|---|---|
| PA3 | ODA/PDA | 50/50 | Only ODPA | 0.11 | 288 | 38 |
| PA4 | ODA/KF8010 | 70/30 | Only BPADA | <0.01 | 200 | 113 |

### Preparation of Particle Dispersion

Hereinafter, a method of preparing a particle dispersion used in Examples and Comparative Examples will be described.

### Preparation of Particle Dispersion PD1

A mixture of 20 g of a fumed silica particle (“AEROSIL E9200” manufactured by NIPPON AEROSIL CO., LTD., apparent specific gravity: 80 to 120 g/L) and 80 g of DMF was stirred with a rotary blade homogenizer (diameter of rotary blade: 20 mm) at a rotation speed of 10,000 rpm for 5 minutes to obtain a particle dispersion PD1.

### Preparation of Particle Dispersion PD2

A particle dispersion PD2 was obtained by a method the same as the method of preparing the particle dispersion PD1 except that 20 g of a fumed silica particle (“AEROSIL R9200” manufactured by NIPPON AEROSIL CO., LTD., apparent specific gravity: 200 g/L) was used instead of 20 g of the fumed silica particle (“AEROSIL E9200” manufactured by NIPPON AEROSIL CO., LTD.).

### Preparation of Particle Dispersion PD3

A particle dispersion PD3 was obtained by a method the same as the method of preparing the particle dispersion PD1 except that 20 g of a fumed silica particle (“AEROSIL NX130” manufactured by NIPPON AEROSIL CO., LTD., apparent specific gravity: 40 g/L) was used instead of 20 g of the fumed silica particle (“AEROSIL E9200” manufactured by NIPPON AEROSIL CO., LTD.).

### Preparation of Particle Dispersion PD4

A spherical silica particle dispersion (“ADMANANO” manufactured by ADMATECHS COMPANY LIMITED, particle size: 50 nm, dispersion medium: DMF, particle concentration: 20 wt/wt %) was prepared as a particle dispersion PD4.

### Preparation of Particle Dispersion PD5

A particle dispersion PD5 was obtained by mixing 60 g of a spherical silica particle dispersion (“ADMANANO” manufactured by ADMATECHS COMPANY LIMITED, particle size: 10 nm, dispersion medium: DMF, particle concentration: 30 wt/wt %) and 30 g of DMF.

### Production of Metallized Resin Film

Hereinafter, a method of producing a metallized resin film in Examples 1 to 15 and Comparative Examples 1 to 3 will be described.

### Production of Metallized Resin Film of Example 1

### Production of Multilayer Resin Film

A mixture was obtained by mixing 40.0 g of the polyamic acid solution PA1 and 17.0 g of the particle dispersion PD1, and 40 g of DMF was added to the mixture to obtain a layer A-forming dispersion. Next, the layer A-forming dispersion was applied onto one surface of a non-thermoplastic polyimide film (“APICAL FP” manufactured by KANEKA CORPORATION, thickness: 17 μm, linear expansion coefficient: 12 ppm/K) so that the thickness after imidization was 4 μm, and dried at a temperature of 120° C. for 2 minutes. Next, the layer A-forming dispersion was similarly applied onto the other surface of the non-thermoplastic polyimide film so that the thickness after imidization was 4 μm, and dried at a temperature of 120° C. for 2 minutes. Next, the non-thermoplastic polyimide film coated with the layer A-forming dispersion was heated at a temperature of 450° C. for 12 seconds to imidize the polyamic acid in the layer A-forming dispersion, and thus a multilayer resin film was obtained in which the layer A (layer containing a polyimide and a fumed silica particle)/the layer D (non-thermoplastic polyimide layer)/the layer A were stacked in this order.

### Desmear Treatment

Next, both surfaces of the multilayer resin film obtained in the above procedure were desmear-treated under the conditions shown in Table 2, and after wiping moisture from the multilayer resin film surfaces, the surfaces were dried using a dryer and air-dried for 12 hours. The chemical solution used for each desmear treatment was manufactured by Atotech. In addition, a water washing step was performed between steps and after the neutralization step.

TABLE 2

| | | | | Treatment | Treatment |
|---|---|---|---|---|---|
| | Treatment solution | | | temperature | time |
| | Product name, etc. | Concentration | | [° C.] | [min] |
| Swelling step | Securiganth P Sweller | 500 | mL/L | 60 | 5 |
| | NaOH | 3 | g/L | | |
| Roughening step | Compact CP Concentrate | 600 | mL/L | 80 | 5 |
| | NaOH | 40 | g/L | | |
| Neutralization step | Securiganth P500 Reduction | 100 | mL/L | 40 | 5 |
| | Solution | | | | |
| | Sulfuric acid | 90 | mL/L | | |
| | (concentration: 50 wt %) | | | | |

### Electroless Copper Plating Treatment

Next, both the surfaces of the multilayer resin film after the desmear treatment were each subjected to an electroless copper plating treatment under the conditions shown in Table 3, and after wiping moisture from the electroless copper plating layer surfaces, the surfaces were dried using a dryer (80° C.×30 minutes). By the above procedure, a metallized resin film of Example 1 was obtained that had both surfaces each provided with an electroless copper plating layer having a thickness of 0.5 to 1.0 μm. The chemical solution used for each electroless copper plating treatment was manufactured by Atotech. In addition, a water washing step was performed between steps and after the electroless copper plating step.

TABLE 3

| | | | | Treatment | Treatment |
|---|---|---|---|---|---|
| | Treatment solution | | | temperature | time |
| | Product name, etc. | Concentration | | [° C.] | [min] |
| Washing Step | Securiganth 902 Cleaner | 40 | mL/L | 60 | 4 |
| | NaOH | 20 | g/L | | |
| Soft etching step | Sodium peroxodisulfate | 150 | g/L | 30 | 1 |
| | Sulfuric acid | 35 | g/L | | |
| | (concentration: 50 wt %) | | | | |
| Pre-dip step | Neoganth B Pre Dip | 10 | mL/L | 23 | 1 |
| Pd applying step | Neoganth Activator 834 | 40 | mL/L | 40 | 4 |
| Reduction step | Neoganth WA Reducer | 6 | mL/L | 30 | 3 |
| | Reducer Accelarator 810 mod. | 100 | mL/L | | |
| Electroless copper | Printoganth MV Basic TP1 | 140 | mL/L | 34 | 10 |
| plating step | Printoganth MV Copper TP1 | 85 | mL/L | | |
| | Printoganth MV Modetator TP1 | 3 | mL/L | | |
| | Printoganth MV Stabilizer TP1 | 0.6 | mL/L | | |
| | Cu Reduction Solution | 16 | mL/L | | |
| | NaOH | 3 | g/L | | |

### Production of Metallized Resin Film of Example 2

A metallized resin film of Example 2 was obtained by a method the same as the production method of Example 1 except that 17.0 g of the particle dispersion PD2 was used instead of 17.0 g of the particle dispersion PD1.

### Production of Metallized Resin Film of Example3

A metallized resin film of Example 3 was obtained by a method the same as the production method of Example 1 except that 17.0 g of the particle dispersion PD3 was used instead of 17.0 g of the particle dispersion PD1.

### Production of Metallized Resin Film of Example 4

A metallized resin film of Example 4 was obtained by a method the same as the production method of Example 1 except that the amount of the particle dispersion PD1 was changed to 8.5 g.

### Production of Metallized Resin Film of Example 5

A metallized resin film of Example 5 was obtained by a method the same as the production method of Example 1 except that the amount of the particle dispersion PD1 was changed to 11.9 g.

### Production of Metallized Resin Film of Example 6

A metallized resin film of Example 6 was obtained by a method the same as the production method of Example 1 except that the amount of the particle dispersion PD1 was changed to 27.2 g.

### Production of Metallized Resin Film of Example 7

A metallized resin film of Example 7 was obtained by a method the same as the production method of Example 1 except that 11.2 g of the particle dispersion PD4 was used instead of 17.0 g of the particle dispersion PD1.

### Production of Metallized Resin Film of Example 8

A metallized resin film of Example 8 was obtained by a method the same as the production method of Example 1 except that 11.2 g of the particle dispersion PD5 was used instead of 17.0 g of the particle dispersion PD1.

### Production of Metallized Resin Film of Example 9

A metallized resin film of Example 9 was obtained by a method the same as the production method of Example 1 except that 40.0 g of the polyamic acid solution PA2 was used instead of 40.0 g of the polyamic acid solution PA1.

### Production of Metallized Resin Film of Example 10

A metallized resin film of Example 10 was obtained by a method the same as the production method of Example 1 except that 40.0 g of the polyamic acid solution PA3 was used instead of 40.0 g of the polyamic acid solution PA1.

### Production of Metallized Resin Film of Examples 11 to 15

A metallized resin film of each of Examples 11 to 15 was obtained by a method the same as the production method of Example 1 except that the treatment time in each step of the desmear treatment (swelling step, roughening step, and neutralization step) was changed to the treatment time shown in Table 5 described below.

### Production of Metallized Resin Film of Comparative Example 1

A metallized resin film of Comparative Example 1 was obtained by a method the same as the production method of Example 1 except that 40 g of DMF was added to 40.0 g of the polyamic acid solution PA1 without using the particle dispersion PD1 to obtain a layer A-forming dispersion.

### Production of Metallized Resin Film of Comparative Example 2

A metallized resin film of Comparative Example 2 was obtained by a method the same as the production method of Example 1 except that 40.0 g of the polyamic acid solution PA4 was used instead of 40.0 g of the polyamic acid solution PA1.

### Production of Metallized Resin Film of Comparative Example 3

A metallized resin film of Comparative Example 3 was obtained by a method the same as the production method of Example 1 except that the desmear treatment was not performed.

### Evaluation Method

Hereinafter, a method of evaluating the metallized resin film in each of Examples 1 to 15 and Comparative Examples 1 to 3 will be described.

### Light Reflectance

First, each metallized resin film was cut out into a size of 15 mm×50 mm, and the copper layer on one surface of the film was completely removed with an acid etching solution (ferric chloride solution) to obtain a sample having the layer B only on one surface of the multilayer resin film. Hereinafter, in the main surfaces of the multilayer resin film of the sample, the main surface on which the layer B is not provided is described as the “first main surface”, and the main surface on which the layer B is provided is described as the “second main surface”. In a case where the layer C is formed on both the main surfaces of the multilayer resin film, the layer C on the first main surface side is removed by the etching solution. Therefore, on the first main surface, the layer C formed on the second main surface side is observed through the multilayer resin film.

Next, light was emitted to be incident on the first main surface side of the sample, and thus the light reflectance of the first main surface was measured. Specifically, the light reflectance was measured in a wavelength range of 300 nm to 800 nm at intervals of 1 nm using an ultraviolet/visible/near-infrared spectrophotometer (“V-770” manufactured by JASCO Corporation) and an integrating sphere unit (“ISN-923” manufactured by JASCO Corporation), and the average reflectance at all of the wavelengths in the range of 300 nm to 800 nm was determined. The obtained average reflectance was taken as the “light reflectance” described in Table 5 below. In a case where the sample including the layer C is used, the light reflectance obtained here is the light reflectance of the layer C formed on the second main surface side.

### Confirmation of Presence of Ionic Copper

Each metallized resin film was cut obliquely from one layer B side with a surface and interfacial cutting analysis system (hereinafter, described as “SAICAS”) under the following conditions to obtain a section (oblique section) obtained by oblique cutting from the layer B to the layer A.

### Cutting Conditions

Apparatus: “SAICAS DN-20S” manufactured by DAIPLA WINTES CO., LTD.
Material of cutting blade: Diamond
Blade width of cutting blade: 1.0 mm
Rake angle: 2°
Clearance angle: 10°
Measurement mode: Constant speed mode

Next, the boundary portion between the layer A and the layer B in the obtained oblique section was observed using a camera attached to the SAICAS. At this time, in a case where a black belt-shaped portion was observed in the boundary portion between the layer A and the layer B, the black belt-shaped portion was determined to be the layer C.

In such a case where a black belt-shaped portion was observed, the belt-shaped portion was analyzed by X-ray photoelectron spectroscopy (XPS) under the following conditions. In a case where a black belt-shaped portion was not observed, the layer A portion was analyzed by XPS under the following conditions so that the measurement spot did not include the layer B (electroless copper plating layer). Next, in the obtained CuLMM spectrum, in a case where the main peak observed in the binding energy range of 575 to 565 eV had a binding energy in the range of 573 to 568.5 eV, the main state of the copper element was determined to be copper having ionicity (ionic copper).

### XPS Analysis Conditions

Apparatus: “PHI 5000 VersaProbe II” manufactured by ULVAC-PHI, Inc.
X-ray source: Monochromatic AlKα radiation
X-ray intensity: 15 kV (12.5 W)
Measurement range: 50 μmΦ
Pass energy (wide): 187.85 eV
Pass energy (narrow): 58.70 eV
Charge correction: 284.6 eV (C1s)

In each of the metallized resin films of Examples 1 to 15 and Comparative Example 2, the black belt-shaped portion was observed, and the main state of the copper element present in the black belt-shaped portion was confirmed to be ionic copper by XPS. Meanwhile, in the metallized resin films of Comparative Examples 1 and 3, the black belt-shaped portion was not observed, and presence of ionic copper was not confirmed from the XPS analysis results.

### Solder Heat Resistance

### Production of Double-Sided Copper-Clad Laminate

Both surfaces of each metallized resin film were subjected to an electrolytic copper plating treatment under the conditions shown in Table 4, and after wiping moisture from the electrolytic copper plating layer surfaces, the surfaces were dried using a dryer (80° C. ×30 minutes). Thus, a double-sided copper-clad laminate was obtained that had both surfaces each provided with an electrolytic copper plating layer having a thickness of 30 μm. The chemical solution used in each electrolytic copper plating step was manufactured by Atotech. In addition, a water washing step was performed between the acid washing step and the electrolytic copper plating step and after the electrolytic copper plating step.

TABLE 4

| | Treatment solution | | | |
|---|---|---|---|---|
| | Product name, etc. | Concentration | | Treatment condition |
| Acid washing | “PC-316” manufactured by Meltex | Used without | | 45° C. × 3 min |
| step | Inc. | dilution | | |
| Electrolytic | Copper sulfate pentahydrate | 80 | g/L | Plating bath |
| copper plating | Sulfuric acid (concentration: 98 wt %) | 200 | g/L | temperature: 23° C. |
| step | Chloride ion (added as hydrochloric | 50 | mg/L | Current density: 2 ASD |
| | acid) | | | |
| | Leveller Cupracid TP1 | 20 | mL/L | Plating time: |
| | Brightener Cupracid Universal | 0.6 | mL/L | 2.3 min/μm |

### Procedure of Evaluating Solder Heat Resistance

The obtained double-sided copper-clad laminate was cut out into a size of 3.5 cm square. Then, the cut-out double-sided copper-clad laminate was etched with an acid etching solution (ferric chloride solution) so that the copper plating layer (the electroless copper plating layer and the electrolytic copper plating layer) of 2.5 cm square remained at the center of one main surface (hereinafter, sometimes described as “surface A”), and the entire surface of the copper plating layer (the electroless copper plating layer and the electrolytic copper plating layer) remained on the other main surface (hereinafter, sometimes described as “surface B”) to obtain an evaluation sample. For each of Examples and Comparative Examples, 10 evaluation samples were produced as described above, then each evaluation sample was allowed to stand for 96 hours under humidified conditions of a temperature of 40° C. and a humidity of 90% RH, and thus a moisture absorption treatment was performed.

After the moisture absorption treatment, 5 of the 10 evaluation samples were immersed in a solder bath at 260° C. or 300° C. for 10 seconds. That is, for each of Examples and Comparative Examples, 5 evaluation samples were used under one temperature condition. Then, for each evaluation sample after the immersion in a solder bath, the copper plating layer on the surface B was completely removed with an acid etching solution (ferric chloride solution), and the appearance of the center portion of the surface B after removal of the copper plating layer was visually observed. In a case where at least one of whitening, swelling, or peeling of the copper plating layer on the surface A was confirmed by appearance observation, the appearance change was determined to be present. Then, the evaluation result was determined to be A (extremely excellent in solder heat resistance) in a case where all of the 5 evaluation samples were not changed in appearance under the temperature condition of 300° C., the evaluation result was determined to be B (excellent in solder heat resistance) in a case where at least one of the 5 evaluation samples was changed in appearance under the temperature condition of 300° C. and all of the 5 evaluation samples were not changed in appearance under the temperature condition of 260° C., and the evaluation result was determined to be C (not excellent in solder heat resistance) in a case where at least one of the 5 evaluation samples was changed in appearance under the temperature condition of 260° C.

### Peel Strength

First, for each of Examples and Comparative Examples, a double-sided copper-clad laminate was produced with the same procedure as the double-sided copper-clad laminate produced in the evaluation of the solder heat resistance. The copper plating layer on one side of the obtained double-sided copper-clad laminate was etched using a masking tape and an acid etching solution (ferric chloride solution) to form a copper pattern having a width of 1 mm, and thus a measurement sample was obtained.

Next, in accordance with JIS C 6471-1995, the peel strength was determined to be the average peel strength obtained by peeling the copper pattern from the layer A by 50 mm using a tensile tester (“Strograph VES 1D” manufactured by Toyo Seiki Seisaku-sho, Ltd.) in an environment of a temperature of 23° C. and a humidity of 55% RH under the conditions of a tensile speed of 50 mm/min and a peel angle of 180°.

### Arithmetic Average Roughness Ra

First, for each of Examples and Comparative Examples, a double-sided copper-clad laminate was produced with the same procedure as the double-sided copper-clad laminate produced in the evaluation of the solder heat resistance. The entire surfaces of the copper plating layers on both surfaces of the obtained double-sided copper-clad laminate were etched using an acid etching solution (ferric chloride solution) to remove the copper plating layers completely. The arithmetic average roughness Ra of one surface (one main surface) of the etched multilayer resin film was measured in accordance with JIS C 0601-2001 using a scanning probe microscope (“Dimmension Icon” manufactured by Bruker Corporation).

### Capability of Narrowing of Pitch

The metallized resin film was evaluated to be “a metallized resin film capable of coping with formation of a circuit having a narrow pitch” in a case where the peel strength obtained by the above measurement method and the arithmetic average roughness Ra obtained by the above measurement method satisfy the following condition A. Meanwhile, the metallized resin film was evaluated to be “not a metallized resin film capable of coping with formation of a circuit having a narrow pitch” in a case where the peel strength obtained by the above measurement method and the arithmetic average roughness Ra obtained by the above measurement method satisfy the following condition B or C.

Condition A: The peel strength is 5 N/cm or more, and the arithmetic average roughness Ra is 220 nm or less.

Condition B: The peel strength is less than 5 N/cm, or the arithmetic average roughness Ra is more than 220 nm.

Condition C: The peel strength is less than 5 N/cm, and the arithmetic average roughness Ra is more than 220 nm.

### Results

For each of the metallized resin films of Examples 1 to 15 and Comparative Examples 1 to 3, Table 5 shows the used polyamic acid solution, the used particle dispersion, the amount of the particle, the treatment time of each step in the desmear treatment, the light reflectance, the solder heat resistance, the peel strength, and the arithmetic average roughness Ra. The numerical value in the column of “Amount of particle” in Table 5 is the amount (unit: part by weight) of the particle (silica particle) in the layer A with respect to 100 parts by weight of the polyimide in the layer A. The heading “Treatment time” in Table 5 means the treatment time of each step in the desmear treatment. The note “—” in Table 5 means that the desmear treatment was not performed.

TABLE 5

| | | Particle dispersion | | | | | | | |
|---|---|---|---|---|---|---|---|---|---|
| | | | Apparent | | | | | | Arithmetic |
| | | | specific | Amount of | | | | | average |
| | Polyamic | | gravity of | particle | Treatment | Light | Solder | Peel | roughness |
| | acid | | particle | [parts by | time | reflectance | heat | strength | Ra |
| | solution | Kind | [g/L] | weight] | [min] | [%] | resistance | [N/cm] | [nm] |
| Example 1 | PA1 | PD1 | 80-120 | 53 | 5 | 7 | A | 18 | 110 |
| Example 2 | PA1 | PD2 | 200 | 53 | 5 | 8 | A | 14 | 98 |
| Example 3 | PA1 | PD3 | 40 | 53 | 5 | 9 | A | 10 | 118 |
| Example 4 | PA1 | PD1 | 80-120 | 27 | 5 | 18 | A | 6 | 60 |
| Example 5 | PA1 | PD1 | 80-120 | 37 | 5 | 14 | A | 12 | 80 |
| Example 6 | PA1 | PD1 | 80-120 | 85 | 5 | 15 | A | 10 | 140 |
| Example 7 | PA1 | PD4 | >1,000 | 35 | 5 | 14 | B | 5 | 80 |
| Example 8 | PA1 | PD5 | >1,000 | 35 | 5 | 10 | A | 7 | 73 |
| Example 9 | PA2 | PD1 | 80-120 | 53 | 5 | 8 | A | 18 | 94 |
| Example 10 | PA3 | PD1 | 80-120 | 54 | 5 | 7 | A | 14 | 118 |
| Example 11 | PA1 | PD1 | 80-120 | 53 | 1 | 19 | A | 9 | 80 |
| Example 12 | PA1 | PD1 | 80-120 | 53 | 2.5 | 7 | A | 17 | 91 |
| Example 13 | PA1 | PD1 | 80-120 | 53 | 7.5 | 9 | A | 13 | 123 |
| Example 14 | PA1 | PD1 | 80-120 | 53 | 10 | 15 | A | 9 | 153 |
| Example 15 | PA1 | PD1 | 80-120 | 53 | 15 | 22 | A | 5 | 210 |
| Comparative | PA1 | Not used | | 0 | 5 | 34 | C | 3 | 21 |
| Example 1 | | | | | | | | | |
| Comparative | PA4 | PD1 | 80-120 | 52 | 5 | 13 | C | 7 | 88 |
| Example 2 | | | | | | | | | |
| Comparative | PA1 | PD1 | 80-120 | 53 | — | 32 | B | 4 | 95 |
| Example 3 | | | | | | | | | |

In Examples 1 to 15, the layer A (resin composition layer) contained a polyimide having a storage modulus of 0.02 GPa or more at a temperature of 300° C., and contained a metal oxide particle (silica particle). In Examples 1 to 15, the layer C (adhesion layer) contained ionic copper and had a light reflectance of 30% or less.

As shown in Table 5, in Examples 1 to 15, the evaluation result of the solder heat resistance was A (extremely excellent in solder heat resistance) or B (excellent in solder heat resistance). In Examples 1 to 15, the peel strength was 5 N/cm or more, and the arithmetic average roughness Ra was 220 nm or less. Therefore, the metallized resin films of Examples 1 to 15 were a metallized resin film capable of coping with formation of a circuit having a narrow pitch.

In Comparative Example 1, the layer A (resin composition layer) did not contain a metal oxide particle. In Comparative Example 2, the polyimide included in the layer A (resin composition layer) had a storage modulus of less than 0.02 GPa at a temperature of 300° C. In Comparative Examples 1 and 3, no layer C (adhesion layer) containing ionic copper was formed.

As shown in Table 5, in Comparative Examples 1 and 2, the evaluation result of solder heat resistance was C (not excellent in solder heat resistance). In Comparative Examples 1 and 3, the peel strength was less than 5 N/cm. Therefore, the metallized resin films of Comparative Examples 1 and 3 were not a metallized resin film capable of coping with formation of a circuit having a narrow pitch.

From the above results, it has been shown that, according to one or more embodiments of the present invention, a metallized resin film can be provided that is excellent in solder heat resistance and capable of coping with formation of a circuit having a narrow pitch.

### DESCRIPTION OF REFERENCE SIGNS

10, 20, 30 metallized resin film
11 layer A (resin composition layer)
12 layer B (electroless copper plating layer)
13 layer C (adhesion layer)

Although the disclosure has been described with respect to only a limited number of embodiments, those skilled in the art, having benefit of this disclosure, will appreciate that various other embodiments may be devised without departing from the scope of the present disclosure. Accordingly, the scope of the invention should be limited only by the attached claims.

1. A metallized resin film comprising:
a resin composition layer;
an electroless copper plating layer; and
an adhesion layer comprising ionic copper interposed between the resin composition layer and the electroless copper plating layer, wherein:
the resin composition layer comprises a metal oxide particle and a polyimide-based resin having a storage modulus of 0.02 GPa or more at a temperature of 300° C.; and
the adhesion layer has a light reflectance of 30% or less.

2. The metallized resin film according to claim 1, wherein the metal oxide particle is a silica particle.

3. The metallized resin film according to claim 2, wherein the silica particle is a fumed silica particle.

4. The metallized resin film according to claim 1, wherein the polyimide-based resin has a linear expansion coefficient of 30 ppm/K or more and 100 ppm/K or less.

5. The metallized resin film according to claim 1, wherein the polyimide-based resin has one or more diamine residues selected from the group consisting of a 2,2′-bis(trifluoromethyl)benzidine residue, a 4,4′-oxydianiline residue, a 1,3-bis(4-aminophenoxy)benzene residue, a 2,2-bis[4-(4-aminophenoxy)phenyl]propane residue, a 2,2′-dimethylbenzidine residue, and a p-phenylenediamine residue, and one or more tetracarboxylic dianhydride residues selected from the group consisting of a 4,4′-oxydiphthalic anhydride residue, a 3,3′,4,4′-biphenyltetracarboxylic dianhydride residue, and a pyromellitic dianhydride residue.

6. The metallized resin film according to claim 1, wherein a surface of the resin composition layer facing towards the adhesion layer has an arithmetic average roughness Ra of 220 nm or less.

7. A printed wiring board comprising the metallized resin film according to claim 1.

8. A current collector film for lithium ion batteries, comprising the metallized resin film according to claim 1.

9. A method for manufacturing a metallized resin film, the method comprising:
conducting a desmear treatment on a resin composition layer; and
forming an electroless copper plating layer on the resin composition layer, wherein the resin composition layer comprises a metal oxide particle and a polyimide-based resin having a storage modulus of 0.02 GPa or more at a temperature of 300° C.
